(19) United States
(12) Patent Application Publication
(10) Pub. No.: US 2025/0359472 A1
(43) Pub. Date: Nov. 20, 2025

(54) FULLERENE-FUNCTIONALIZED VINYL POLYMERS AND PREPARATION PROCESS THEREOF

(71) Applicant: ENI S.P.A., Roma (RM) (IT)

(72) Inventors: Paolo BIAGINI, Novara (NO) (IT); Riccardo PO', Novara (NO) (IT); Francesco GIACALONE, Palermo (PA) (IT); Carla CALABRESE, Palermo (PA) (IT)

(21) Appl. No.: 19/120,135

(22) PCT Filed: Oct. 10, 2023
(86) PCT No.: PCT/IB2023/060156

§ 371 Date: Apr. 10, 2025

(30) Foreign Application Priority Data
Oct. 11, 2022 (IT) 102022000020952

(51) Int. Cl. H10K 85/20; H10K 10/46; H10K 30/50; H10K 30/85; H10K 85/10

(52) U.S. Cl. CPC H10K 85/215; H10K 10/46; H10K 30/50; H10K 30/85; H10K 85/141

(57) ABSTRACT

Fullerene-functionalized vinyl polymer having general formula (I):

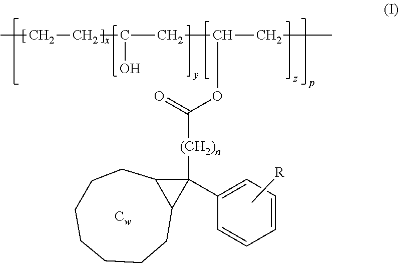

wherein:
x is a fractional number comprised between 0 and 0.89;
y is a fractional number comprised between 0.01 and 0.9;
z is a fractional number comprised between 0.1 and 0.99;
provided that the sum of x+y+z is equal to 1;
p is an integer comprised between 10 and 10000;
w is an integer comprised between 50 and 250;
n is an integer comprised between 1 and 12;
R represents a hydrogen atom; or is selected from C₁-C₂₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups.

Said fullerene-functionalized vinyl polymer having general formula (I) can advantageously be used as an electron acceptor compound in organic photovoltaic devices (or solar devices).

### CROSS-REFERENCE TO RELATED APPLICATIONS

This application is a 35 U.S.C. § 371 National Stage patent application of PCT/IB2023/060156, filed on 10 Oct. 2023, which claims the benefit of Italian patent application 102022000020952, filed on 11 Oct. 2022, the disclosures of which are incorporated herein by reference in their entirety.

### TECHNICAL FIELD

The present disclosure relates to fullerene-functionalized vinyl polymers.

More specifically, the present disclosure relates to a fullerene-functionalized vinyl polymer having the specific general formula (I) hereinafter reported.

Said fullerene-functionalized vinyl polymer having general formula (I) can advantageously be used as an electron acceptor compound in organic photovoltaic devices (or solar devices) such as, for example, binary, ternary, quaternary, organic photovoltaic cells (or solar cells) having simple or “tandem” architecture, organic photovoltaic modules (or solar modules), on a rigid support or on a flexible support. Furthermore, said fullerene-functionalized vinyl polymer having general formula (I) can advantageously be used in perovskite-based photovoltaic cells (or solar cells) in the electron transport layer (ETL). Furthermore, said fullerene-functionalized vinyl polymer having general formula (I) can advantageously be used in the production of organic thin-film transistors (OTFTs), or organic field effect transistors (OFETs).

Further subject matter of the present disclosure is a process for the preparation of said fullerene-functionalized vinyl polymer having general formula (I).

The present disclosure also relates to an organic photovoltaic device (or solar device) such as, for example, an organic, binary, ternary, quaternary solar cell, having a simple or a “tandem” architecture, an organic photovoltaic module (or solar module), on a rigid support or on a flexible support, comprising at least one fullerene-functionalized vinyl polymer having the specific general formula (I).

The present disclosure also relates to a perovskite-based photovoltaic cell (or solar cell) wherein the electron transport layer (ETL) comprises at least one fullerene-functionalized vinyl polymer having the specific general formula (I).

The present disclosure also relates to organic thin-film transistors (OTFTs), or organic field-effect transistors (OFETs) comprising at least one fullerene-functionalized vinyl polymer having the specific general formula (I).

In the simplest way of operating, organic photovoltaic cells (or solar cells) are manufactured by introducing between two electrodes, usually consisting of indium-tin oxide (ITO) (anode) and aluminium (Al) (cathode), a photoactive thin layer (about 100 nanometres) of a mixture of an electron acceptor compound and an electron donor compound (an architecture known as “bulk heterojunction”). Generally, in order to make a layer of this type, a solution of the two compounds is prepared and, subsequently, a photoactive film is formed on the anode [indium-tin oxide (ITO)] starting from said solution, using suitable deposition techniques such as, for example, “spin-coating”, “spray-coating”, “ink-jet printing”, and the like. Finally, the counter electrode [i.e. the aluminium cathode (Al)] is deposited on the dried film. Optionally, other additional layers can be introduced between the electrodes and the photoactive film, which layers are capable of performing specific functions of an electrical, optical, or mechanical nature.

Generally, in order to facilitate the achievement of the anode [indium-tin oxide (ITO)] by the electronic gaps (or holes) and at the same time to block the transport of electrons, thus improving the harvest of charges by the electrode and inhibiting the recombination phenomena, before creating the photoactive film starting from the mixture of the acceptor compound and the donor compound as described above, a film is deposited starting from an aqueous suspension of PEDOT:PSS [poly(3,4-ethylenedixythiophene)polystyrene sulfonate], using suitable deposition techniques such as, for example, “spin-coating”, “spray-coating”, “ink-jet printing”, and the like.

In the vast majority of cases, the electron acceptor compound is selected from C₆₀, C₇₀ fullerene derivatives such as, for example, [6,6]-phenyl-C₆₁-butyric acid methyl ester (PC61BM), (6,6)-phenyl-C₇₁-butyric acid methyl ester (PC71BM). However, said fullerene derivatives show poor solubility in the solvents normally used for the construction of photovoltaic cells (or solar cells) and a certain tendency to segregate in the aforesaid photoactive layer.

One way to overcome the aforesaid drawbacks was to incorporate C₆₀ fullerene or C₇₀ fullerene into polymeric structures as reported, for example, by Giacalone F. et al. in “Chemical Reviews” (2006), Vol. 106, No. 12, pg. 5136-5190; Giacalone F. et al., in “Advanced Materials” (2010), Vol. 22, pg. 4220-4248.

Among the several attempts to incorporate fullerene into polymeric structures, mention must be made of the use of acrylates and methacrylates as basic macromolecules. Synthetic strategies for the preparation of fullerene-containing (meth)acrylic polymers are in such an advanced state that it is possible to synthesise a whole range of even highly complex structures by means of the most diverse polymerisation techniques: from the traditional radical polymerisation to the more sophisticated atom transfer radical polymerisation (ATRP). Thereby, (meth)acrylic copolymers containing random-type fullerene, or (meth)acrylic copolymers containing block-type fullerene, having high or low molecular weights and varying polydispersity indices, can be obtained.

The category of (meth)acrylic copolymers containing side-chain fullerene is one of the most studied. However, the most immediate strategy, i.e. the synthesis of fullerene-functionalized (meth)acrylic monomers and their subsequent co-polymerisation by the radical route does not lead to the desired polymers as reported, for example, by Mehrotra S. et al., in “Chemical Communications” (1997), pg. 463-464; Kirkwood K. et al., in “Journal of Polymer Science Part A: Polymer Chemistry” (1997), Vol. 35, Issue 15, pg. 3323-3325. The authors report, in fact, that during polymerisation, C₆₀ fullerene not only delays the polymerisation process but also undergoes multiple and random addition of radical chains, producing complex polymer mixtures that cannot be reproduced and are even partially cross-linked, which makes the obtained polymers insoluble and, therefore, not suitable for use for the purposes of the present disclosure.

Further examples of C₆₀ fullerene-functionalized poly(alkyl)methacrylates and poly(hydroxyalkyl)methacrylates are reported by Zheng J. et al., in “Polymer Bulletin” (1997), Vol. 39, pg. 79-84; Lu Z. H. et al., in “Polymer Bulletin” (1997), Vol. 39, pg. 661-667; Huang H. L. et al., in “Langmuir” (2003), Vol. 19, pg. 5332-5335; Goh H. W. et al., in “Journal of Polymer Science Part A: Polymer Chemistry” (2002), Vol. 40, Issue 8, pg. 1157-1166. The authors report the synthesis of copolymers containing different amounts of alkyl methacrylates such as, for example, methyl methacrylate, ethyl methacrylate, butyl methacrylate, or hydroxyalkyl methacrylates such as, for example, 2-hydroxyethyl methacrylate, 3-hydroxypropyl methacrylate, or 6-hydroxyhexyl methacrylate. Once the aforementioned methacrylate copolymers have been prepared, the hydroxyl groups are converted in two steps to azides, resulting in azido-polymers that can react with fullerene to give the desired C₆₀ functionalized methacrylate copolymers with a C₆₀ fullerene content comprised between 0.6% by weight and 7.4% by weight. The C₆₀ fullerene-functionalized methacrylate copolymers deriving from alkyl methacrylates are soluble in tetrahydrofuran (THF), chlorobenzene, or chloroform, while those deriving from hydroxyalkyl methacrylates are soluble in dimethylformamide (DMF), or methanol.

It should be noted, however, that the use of the aforesaid azido-polymers has the drawback that non-reacted azido groups can subsequently generate cross-linking processes that lead to materials that are not stable over time and cannot be processed and, therefore, cannot be used for the purposes of the present disclosure.

Sato H. et al, in “Polymer Bullettin” (2015), Vol. 72, No. 11, pg. 904-909, report the preparation of two different fullerene-containing methylacrylate monomers by the reaction of fullerene with 4-azidobenzoyloxyethyl methacrylate or with 4-azidobenzoyloxyethyl methacrylate. It is interesting to observe that the tests of subsequent anionic copolymerization (with Grignard reagent) allow polymers to be obtained with a low weight average molecular weight (Mw) but a maximum of 10.5% by weight of C₆₀ fullerene, while radical polymerisation in the presence of α,α′-azo-isobutyronitrile (AIBN) as the radical initiator, fails, further confirming that the acrylic monomers of C₆₀ cannot be radically polymerised.

Ladelta V. et al, in “Polymer Bulletin” (2015), Vol. 72, pg. 1265-1280, report polymethyl methacrylates having a high C₆₀ fullerene content (i.e. up to 41.4% by weight) obtained by reaction, in chlorobenzene, of azide-containing copolymers derived from random copolymers of 6-chlorohexyl methacrylate and methyl methacrylate with C60 fullerene, said polymethyl methacrylates being soluble in common organic solvents such as chloroform (CHCl₃), tetrahydrofuran (THF) and toluene. Size exclusion chromatography (SEC) shows that said polymethyl methacrylates form intra- and inter-molecular aggregations in chloroform (CHCl₃), presumably due to the strong interactions between the C60 fullerene pendant groups, whereas they do not form them in tetrahydrofuran.

Tollan C. M. et al., in “New Journal of Chemistry” (2008), Vol. 32, pg. 1373-1378, report a method for the synthesis of acrylic polymers containing C₆₀ fullerene that first involves the synthesis of a monosubstituted C₆₀ fullerene (i.e. mono-fulleropyrrolidine) that is subsequently reacted with an acryloyl chloride/methyl acrylate copolymer. The amine group of mono-fulleropyrrolidine reacts with the acyl-chloride group of said copolymer to form an amide bond. Said method allowed an acrylic polymer to be obtained containing 44% by weight of C₆₀ fullerene. However, as the authors point out, the presence of acyl chloride groups in the final polymer, due to an incomplete substitution with the fulleropyrrolidine reagent, makes these materials not very stable over time due to the high reactivity of the acyl chloride groups with moisture in the air. This drawback results in progressive cross-linking of the materials that makes them insoluble and therefore not suitable for use for the purposes of the present disclosure, as highlighted by the authors for the polymer with the highest fullerene content (P4), which is already insoluble as soon as it is prepared.

Li J. et al., in “Journal of Materials Chemistry” (2009), Vol. 19, pg. 5416-5423, report the synthesis of polymethacrylate containing a high amount of C60 fullerene (up to an average of 78 units of C60 per chain determined by UV-vis). For this purpose, a monoalkynyl fullerene functionalized from pure C60 fullerene was prepared. Subsequently, methyl methacrylate and 6-azido-hexyl methacrylate were randomly copolymerized via RAFT polymerization (“Reversible Addition Fragmentation Chain Transfer Polymerisation”) to obtain a copolymer that was reacted with said monoalkynyl-functionalized fullerene via a copper-mediated “click” reaction, resulting in the aforementioned polymethacrylate. The aforementioned polymethacrylate containing a high amount of C60 fullerene shows, both in solution and in silicon wafers, an interchain “self-aggregation” behaviour that strongly depends on the amount of C60 fullerene present in the chain.

Biglova Y. N. et al., in “Russian Journal of Physical Chemistry B” (2017), Vol. 11, No. 2, pg. 324-329, report the copolymerization and homopolymerization of acrylate-containing fullerenes with vinyl monomers. Fullerene-containing copolymers are said to be easily soluble in common organic solvents, while fullerene-containing homopolymers could not be characterised due to their high degree of cross-linking.

Kötteritzsch J. et al., in “Journal of Applied Polymer Science” (2018), Vol. 135, Issue 10, 45916, report self-healing polymeric materials consisting of poly(lauryl methacrylate) with anthracene units in the side chains to which C60 fullerene and methyl ester of [6,6]-phenyl-C₆₁-butyric acid (PC61BM) were covalently, but reversibly, bonded. The bonds formed by cycloaddition [4+2] between anthracene units and C60 fullerene are reversible and break and reform at 40° C.-60° C. The use of differently substituted anthracene monomers made it possible to adjust the reactivity and the resulting mechanical properties.

However, although the fullerene derivatives known in the art have excellent chemical and physical characteristics for their use in organic photovoltaic devices (or solar devices), they may also have various technical challenges either during the preparation of said photovoltaic devices (or solar devices) or after their use.

As mentioned above, a major drawback is their low solubility in non-toxic solvents and higher solubility in toxic solvents such as, for example, halogenated solvents or carbon disulphide (CS₂). Furthermore, in order to achieve good results in terms of performance of photovoltaic devices (or solar devices), significant quantities of fullerene derivatives must be dispersed within the photoactive layer.

Furthermore, due to the large surface area π-pi, fullerene derivatives have a tendency to segregate even in the solid state within said photoactive layer, causing a drastic reduction in the efficiency of photovoltaic devices (or solar devices) as crystallites of fullerene derivatives are formed limiting the photophysical processes underlying their operation.

Furthermore, the processes for preparing fullerene derivatives are often complex multistep processes not suitable for an industrial process. Furthermore, said processes often use halogenated solvents which, as mentioned above, are toxic and, therefore, not advisable for an industrial process.

The Applicant therefore addressed the problem of finding new fullerene derivatives capable of overcoming the aforesaid drawbacks, as well as a preparation process thereof.

The Applicant has now found a fullerene-functionalized vinyl polymer having the specific general formula (I) hereinafter reported, as well as a process for preparing it, that overcomes the aforesaid drawbacks.

Said fullerene-functionalized vinyl polymer having general formula (I) can advantageously be used as an electron acceptor compound in organic photovoltaic devices (or solar devices) selected, for example, from binary, ternary, quaternary, organic photovoltaic cells (or solar cells) having simple or “tandem” architecture, organic photovoltaic modules (or solar modules), on a rigid support or on a flexible support. Furthermore, said fullerene-functionalized vinyl polymer having general formula (I) can advantageously be used in perovskite-based photovoltaic cells (or solar cells) in the electron transport layer (ETL). Furthermore, said fullerene-functionalized vinyl polymer having general formula (I) can advantageously be used in the production of organic thin-film transistors (OTFTs), or organic field effect transistors (OFETs).

Furthermore, said fullerene-functionalized vinyl polymer having general formula (I) has a good solubility, which ensures that the synthesis process does not lead to cross-linked materials. In particular, said fullerene-functionalized vinyl polymer having general formula (I), in addition to the typical solubility in halogenated solvents such as chloroform, chlorobenzene and dichlorobenzene, has a good solubility in tetrahydrofuran (THF), methyltetrahydrofuran (Me-THF), dimethylsulfoxide (DMSO), dioxane (i.e. a solubility of 30 mg/ml-40 mg/ml), i.e. in solvents considered environmentally “green”. In this regard, it should be noted that both the vast majority of fullerene derivatives and C₆₀ fullerene show almost zero solubility in this type of solvents [i.e. tetrahydrofuran (THF), methyltetrahydrofuran (Me-THF), dimethylsulfoxide (DMSO), dioxane], so the fullerene-functionalized vinyl polymer having general formula (I) can be used within a photovoltaic device either conventionally, by depositing a layer from a solution of chlorobenzene or xylene in the same way as C₆₀ or C₇₀ fullerene derivatives are usually deposited, or in an unconventional manner, i.e. from solutions of solvents such as tetrahydrofuran (THF), methyltetrahydrofuran (Me-THF), dimethylsulfoxide (DMSO), dioxane, thus enabling, for example, a co-deposition with perovskite precursors such as, for example, lead iodide (PbI₂) and methylammonium iodide (MeNH₃I).

Furthermore, said fullerene-functionalized vinyl polymer having general formula (I) can be obtained via a one-step process in the presence of non-halogenated solvents. Furthermore, it should be noted that this process allows to obtain fullerene-functionalized vinyl polymers having general formula (I) containing varying amounts of fullerene and hydroxyl (—OH) groups which are thus capable of creating layers compatible with both hydrophobic and hydrophilic layers of organic photovoltaic devices (or solar devices) or of perovskite-based photovoltaic cells (or solar cells).

Therefore, the subject matter of the present disclosure is a fullerene-functionalized vinyl polymer having general formula (I):

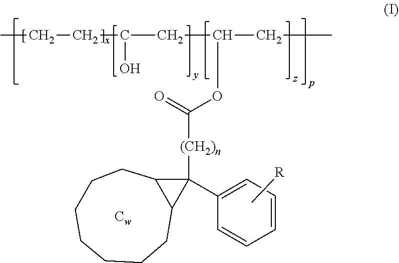

wherein:
x is a fractional number comprised between 0 and 0.89, preferably comprised between 0 and 0.6;
y is a fractional number comprised between 0.01 and 0.9, preferably comprised between 0.02 and 0.7;
z is a fractional number comprised between 0.1 and 0.99, preferably comprised between 0.05 and 0.8;
provided that the sum of x+y+z is equal to 1;
p is an integer comprised between 10 and 10000, preferably comprised between 20 and 5000;
w is an integer comprised between 50 and 250, preferably comprised between 60 and 90, more preferably is 60, 70, 84;
n is an integer comprised between 1 and 12, preferably comprised between 2 and 6;
R represents a hydrogen atom; or is selected from C₁-C₂₀, preferably C₁-C₁₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups; preferably is hydrogen.

For the purpose of the present description and the following claims, the definitions of the numerical intervals always comprise the extreme values unless otherwise specified.

For the purpose of the present description and of the following claims, the term “comprising” also includes the terms “which essentially consists of” or “which consists of”.

For the purpose of the present description and the following claims, the term “C₁-C₂₀ alkyl groups” means linear or branched, saturated or unsaturated, alkyl groups having from 1 to 20 carbon atoms. Specific examples of C₁-C₂₀ alkyl groups are: methyl, ethyl, n-propyl, iso-propyl, n-butyl, iso-butyl, tert-butyl, pentyl, ethyl-hexyl, hexyl, heptyl, n-octyl, nonyl, decyl, dodecyl, 2-octyldodecyl, 2-ethyldodecyl, 2-butyloctyl, 2-hexyldecyl.

For the purpose of the present description and of the following claims, the term “C₁-C₂₀ alkyl groups optionally containing heteroatoms” means linear or branched, saturated or unsaturated, alkyl groups having from 1 to 20 carbon atoms, wherein at least one of the hydrogen atoms is substituted with a heteroatom selected from halogens such as, for example, fluorine, chlorine, bromine, preferably fluorine; nitrogen; sulfur; oxygen. Specific examples of C₁-C₂₀ alkyl groups optionally containing heteroatoms are: fluoromethyl, difluoromethyl, trifluoromethyl, trichloromethyl, 2,2,2-trifluoroethyl, 2,2,2-trichlororoethyl, 2,2,3,3-tetrafluoropropyl, 2,2,3,3,3-pentafluoropropyl, perfluoropentyl, perfluoroctyl, perfluorodecyl, ethyl-2-methoxy, propyl-3-ethoxy, butyl-2-thiomethoxy, hexyl-4-amino, hexyl-3-N,N′-dimethylamino, methyl-N,N′-dioctylamino, 2-methyl-hexyl-4-amino.

For the purpose of the present description and of the following claims, the term “aryl groups” means aromatic carbocyclic groups containing from 6 to 60 carbon atoms. Said aryl groups can optionally be substituted with one or more groups, mutually identical or different, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxy groups; cyano groups; amino groups; C₁-C₁₂ mono- or di-alkylamine groups; nitro groups. Specific examples of aryl groups are: phenyl, methylphenyl, trimethylphenyl, methoxyphenyl, hydroxyphenyl, phenyloxyphenyl, fluorophenyl, pentafluorophenyl, chlorophenyl, bromophenyl, nitrophenyl, dimethylaminophenyl, naphthyl, phenylnaphthyl, phenanthrenene, anthracene.

For the purpose of the present description and of the following claims, the term “heteroaryl groups” means heterocyclic aromatic, penta- or hexa-atomic groups, also benzocondensed or heterobicyclic, containing from 4 to 60 carbon atoms and from 1 to 4 heteroatoms selected from nitrogen, oxygen, sulfur, silicon, selenium, phosphorus. Said heteroaryl group can optionally be substituted with one or more groups, mutually identical or different, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxy groups; cyano groups; amino groups; C₁-C₁₂ mono- or di-alkylamine groups; nitro groups. Specific examples of heteroaryl groups are: pyridine, methylpyridine, methoxypyridine, phenylpyridine, fluoropyridine, pyrimidine, pyridazine, pyrazine, triazine, tetrazine, quinoline, quinoxaline, quinazoline, furan, thiophene, hexylthiophene, bromothiophene, dibromothiophene, pyrrole, oxazole, thiazole, isothiazole, oxadiazole, tiadiazole, pyrazole, imidazole, triazole, tetrazole, indole, benzofuran, benzothiophene, benzooxazole, benzothiazole, benzooxadiazole, benzothiadiazole, benzopyrazole, benzimidazole, benzotriazole, triazolopyridine, triazolopyrimidine, coumarin.

For the purpose of the present description and of the following claims, the term “cycloalkyl groups” means cycloalkyl groups having from 3 to 30 carbon atoms. Said cycloalkyl groups can optionally be substituted with one or more groups, mutually identical or different, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxy groups; cyano groups; amino groups; C₁-C₁₂ mono- or di-alkylamine groups; nitro groups. Specific examples of cycloalkyl groups are: cyclopropyl, 2,2-difluorocyclopropyl, cyclobutyl, cyclopentyl, cyclohexyl, methylcyclohexyl, methoxycyclohexyl, fluorocyclohexyl, phenylcyclohexyl, decalin, abietyl.

For the purpose of the present description and of the following claims, the term “heterocyclic groups” means rings having from 3 to 12 atoms, saturated or unsaturated, containing at least one heteroatom selected from nitrogen, oxygen, sulfur, silicon, selenium, phosphorus, optionally condensed with other aromatic or non-aromatic rings. Said heterocyclic groups can optionally be substituted with one or more groups, mutually identical or different, selected from: halogen atoms, such as fluorine, chlorine, bromine, preferably fluorine, hydroxyl groups, C₁-C₁₂ alkyl groups; C₁-C₁₂ alkoxy groups; C₁-C₁₂ thioalkoxy groups; C₃-C₂₄ tri-alkylsilyl groups; polyethyleneoxy groups; cyano groups; amino groups; C₁-C₁₂ mono- or di-alkylamine groups; nitro groups. Specific examples of heterocyclic groups are: pyrrolidine, methoxypyrrolidine, piperidine, fluoropiperidine, methylpiperidine, dihydropyridine, piperazine, morpholine, thiazine, indoline, phenylindoline, 2-ketoazetidine, diketopiperazine, tetrahydrofuran, tetrahydrothiophene.

For the purpose of the present description and the following claims, the term “C₁-C₂₀ dialkyl-amino groups” means groups comprising a nitrogen atom to which two C₁-C₁₂ alkyl groups are bonded. Specific examples of dialkyl-amino groups are: dimethylamine, diethylamine, dibutylamine, di-iso-butylamine.

For the purpose of the present description and of the following claims, the term “C₁-C₂₀ alkoxy groups” means groups comprising an oxygen atom to which a linear or branched, saturated or unsaturated, C₁-C₂₀ alkyl group is bonded. Specific examples of C₁-C₂₀ alkoxy groups are: methoxy, ethoxy, n-propoxy, iso-propoxy, n-butoxy, iso-butoxy, tert-butoxy, pentoxy, hexyloxy, heptyloxy, octyloxy, nonyloxy, decyloxy, dodecyloxy.

### SUMMARY

According to an embodiment of the present disclosure, said fullerene-functionalized vinyl polymer having general formula (I) has a fullerene content greater than or equal to 35% by weight, preferably comprised between 45% by weight and 75% by weight, with respect to the total weight of said fullerene-functionalized vinyl polymer.

According to an embodiment of the present disclosure, said fullerene-functionalized vinyl polymer having general formula (I) has a content of hydroxyl groups (—OH) greater than or equal to 0.1% by weight, preferably comprised between 0.5% by weight and 15% by weight, with respect to the total weight of said fullerene-functionalized vinyl polymer having general formula (I).

As mentioned above, the present disclosure also relates to a process for the preparation of said fullerene-functionalized vinyl polymer having general formula (I).

Accordingly, further subject matter of the present disclosure is a process for the preparation of a fullerene-functionalized vinyl polymer having general formula (I) comprising reacting at least one vinyl polymer having general formula (II):

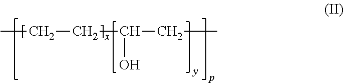

wherein:
x is a fractional number comprised between 0 and 0.99, preferably comprised between 0 and 0.6;
y is an integer or fractional number comprised between 0.01 and 1,
preferably comprised between 0.05 and 0.8;
provided that the sum of x+y is equal to 1;
p is an integer comprised between 10 and 10000, preferably comprised between 20 and 5000;
   with at least one fullerene derivative having general formula (III):

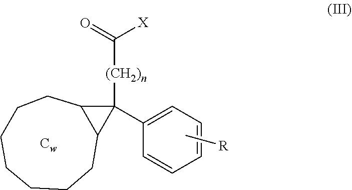

where R, n and w have the same meanings reported above and X represents a hydroxide anion, or a halide anion such as, for example, chloride, bromide, iodide, preferably a hydroxide anion or a chloride anion, more preferably a hydroxide anion;
in the presence of:
an organic solvent or a mixture of organic solvents;
at least one substituted pyridine having general formula (IV):

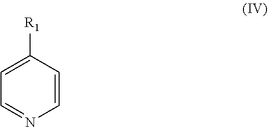

wherein R₁ represents a hydrogen atom; or is selected from C₁-C₂₀, preferably C₁-C₁₀, linear or branched, saturated or unsaturated, alkyl groups optionally containing heteroatoms, optionally substituted aryl groups, optionally substituted heteroaryl groups, optionally substituted cycloalkyl groups, optionally substituted heterocyclic groups; or C₁-C₂₀, preferably C₂-C₁₀, linear or branched, saturated or unsaturated, dialkyl-amino groups, C₁-C₂₀, preferably C₂-C₁₀, linear or branched, saturated or unsaturated, alkoxy groups, amino group, cyano group, hydroxy group; preferably R₁ is methyl, or tert-butyl, or vinyl, dimethyl amino, methoxy, more preferably is dimethyl amino;
at least one substituted carbodiimide having general formula (V):

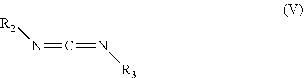

wherein R₂ and R₃, mutually identical or different, are selected from C₁-C₂₀, preferably C₁-C₁₀, linear or branched, saturated or unsaturated, alkyl groups, optionally containing heteroatoms, optionally substituted aryl groups, optionally substituted cycloalkyls, optionally substituted heterocyclic groups; preferably R₂ and R₃ are ethyl, iso-propyl, cyclohexyl, 3-dimethylamino propyl, more preferably cyclohexyl.

According to an embodiment of the present disclosure, said organic solvent can be selected, for example, from dimethylsulphoxide (DMSO), xylene, toluene, mesitylene, tetrahydrofuran (THF), methyltetrahydrofuran (Me-THF), dioxane.

According to another embodiment of the present disclosure, said mixture of organic solvents is a mixture of organic solvents which may be selected, for example, from dimethylsulphoxide (DMSO), xylene, toluene, mesitylene, in a ratio 1/1 v/v, more preferably is a mixture of dimethylsulphoxide (DMSO)/toluene (1/1 v/v), dimethylsulphoxide (DMSO)/xylene (1/1 v/v).

According to an embodiment of the present disclosure, said vinyl polymer having general formula (II) and said fullerene derivative having general formula (III) may be used in a molar ratio with respect to the amount in moles of the —OH groups contained in said vinyl polymer having general formula (II), comprised between 10 and 0.1, preferably comprised between 5 and 0.25, even more preferably comprised between 2.5 and 0.8.

According to another embodiment of the present disclosure said substituted pyridine having general formula (IV) can be selected, for example, from 4-dimethylaminopyridine (DMAP), 4-methylpyridine, 4-tert-butylpyridine, 4-vinylpyridine, 4-methoxypyridine, 4-hydroxypyridine, or mixtures thereof; preferably is 4-dimethylaminopyridine (DMAP).

According to an embodiment of the present disclosure said carbodiimide having general formula (V) may be selected, for example, from N,N′-dimethyl carbodiimide, N,N′-di-iso-propylcarbodiimide, N,N′-di-3-dimethylaminopropyl carbodiimide, N,N′-dicyclohexylcarbodiimide (DCC), or mixtures thereof; preferably is N,N′-dicyclohexylcarboxydiimide (DCC).

According to an embodiment of the present disclosure, said substituted pyridine having general formula (IV) can be used in a molar ratio, with respect to the total moles of the fullerene derivative having general formula (III), comprised between 0.9 and 0.1, preferably comprised between 0.6 and 0.4.

According to an embodiment of the present disclosure, said carbodiimide having general formula (V) can be used in a molar ratio, with respect to the total moles of the fullerene derivative having general formula (III), comprised between 9 and 1, preferably comprised between 6 and 4.

According to an embodiment of the present disclosure, said process can be carried out at a temperature comprised between 15° C. and 150° C., preferably comprised between 20° C. and 90° C.

According to an embodiment of the present disclosure, said process can be carried out for a time comprised between 2 hours and 96 hours, preferably comprised between 20 hours and 90 hours.

As mentioned above, said fullerene-functionalized vinyl polymer having general formula (I) can advantageously be used as an electron acceptor compound in organic photovoltaic devices (or solar devices) such as, for example, binary, ternary, quaternary, organic photovoltaic cells (or solar cells) having simple or “tandem” architecture, organic photovoltaic modules (or solar modules), on a rigid or flexible support. Furthermore, said fullerene-functionalized vinyl polymer having general formula (I) can advantageously be used in perovskite-based photovoltaic cells (or solar cells) in the electron transport layer (ETL). Furthermore, said fullerene-functionalized vinyl polymer having general formula (I) can advantageously be used in the production of organic thin-film transistors (OTFTs), or organic field effect transistors (OFETs).

Accordingly, further subject matter of the present disclosure is an organic photovoltaic device (or solar device) such as, for example, an organic, binary, ternary, quaternary solar cell, having a simple or “tandem” architecture, an organic photovoltaic module (or solar module), on a rigid support or on a flexible support, comprising at least one fullerene-functionalized vinyl polymer having the specific general formula (I).

Further subject matter of the present disclosure is a perovskite-based photovoltaic cell (or solar cell) wherein the electron transport layer (ETL) comprises at least one fullerene-functionalized vinyl polymer having the specific general formula (I).

Additional subject matter of the present disclosure are organic thin film transistors (OTFTs), or organic field effect transistors (OFETs) comprising at least one fullerene-functionalized vinyl polymer having the specific general formula (I).

### DETAILED DESCRIPTION OF THE DISCLOSURE

In order to better understand the present disclosure and to put it into practice, some illustrative and non-limiting examples thereof are reported below.

The following characterisation methods were used in the following examples.

### NMR Spectra

The NMR spectra of the compounds obtained were carried out with an NMR Bruker Avance 400 spectrometer.

For that purpose, about 10 mg of the sample to be examined were dissolved in about 0.8 ml of a suitable deuterated solvent directly on the glass tube used for the measurement. The chemical shift scale was calibrated in relation to the signal of the tetramethylsilane adjusted to 0 ppm.

### FT-IR Spectra

The FT-IR spectra were recorded through Thermo Nicolet Nexus 670 and Bruker IFS 48 spectrophotometers.

The FT-IR spectra of the polymers were obtained from polymeric films on potassium bromide (KBr) tablets, said films being obtained through the deposition of a solution in hot 1,2-dichlorobenzene of the polymer to be analysed. The concentration of the polymeric solutions analysed was equal to 10% by weight with respect to the total weight of the polymeric solution.

### Thermogravimetric Analysis (TGA)

The thermogravimetric analysis (TGA) was carried out using the TA Instruments® Q500 instrument by gradually increasing the temperature from 50° C. to 300° C. (at a rate of 20° C./minute), under a nitrogen atmosphere, and continuously recording the weight variation of the sample.

### Example 1

### Preparation of the Fullerene Derivative PCBA

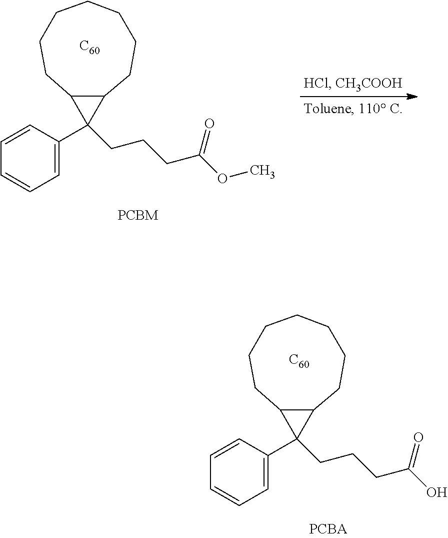 [SMILES: "C60" ; COC(=O)CCCC1(c2ccccc2)C2CCCCCCCC21 ; "C60" ; O=C(O)CCCC1(c2ccccc2)C2CCCCCCCC21]

The preparation of the fullerene derivative PCBA was carried out by hydrolysis of the methyl ester of [6,6]-phenyl-C₆₁-butyric acid (PC61BM) in toluene, according to the procedure reported by Hummelen J. C. et al. in “The Journal of Organic Chemistry” (1995), Vol. 60, pg. 532-538.

For this purpose, 56 ml of concentrated hydrochloric acid (HCl) (VWR—37% aqueous solution) and 139 ml of glacial acetic acid (Merck—purity >97%) were added to a solution of the methyl ester of [6,6]-phenyl-C₆₁-butyric acid (PC61BM) (2 g, 2.2 mmol) (Solenne BV—purity >99%) in 330 ml of toluene (VWR—purity >99.5%) in a 1-litre two-neck flask, equipped with a magnetic stirrer: the obtained reaction mixture was heated and kept at reflux, under stirring, for 48 hours. Subsequently, the temperature was allowed to drop spontaneously to room temperature (25° C.) and the solvent was removed by vacuum evaporation: the residue obtained was washed with diethyl ether (Merck—purity >99%) (3×10 ml), with toluene (Merck—purity >99%) (3×10 ml) and again with diethyl ether (Merck—purity >99%) (2×10 ml) and finally vacuum-dried, at room temperature (25° C.), for 6 hours, resulting in 1.85 g of the fullerene derivative PCBA corresponding to a yield of 94%.

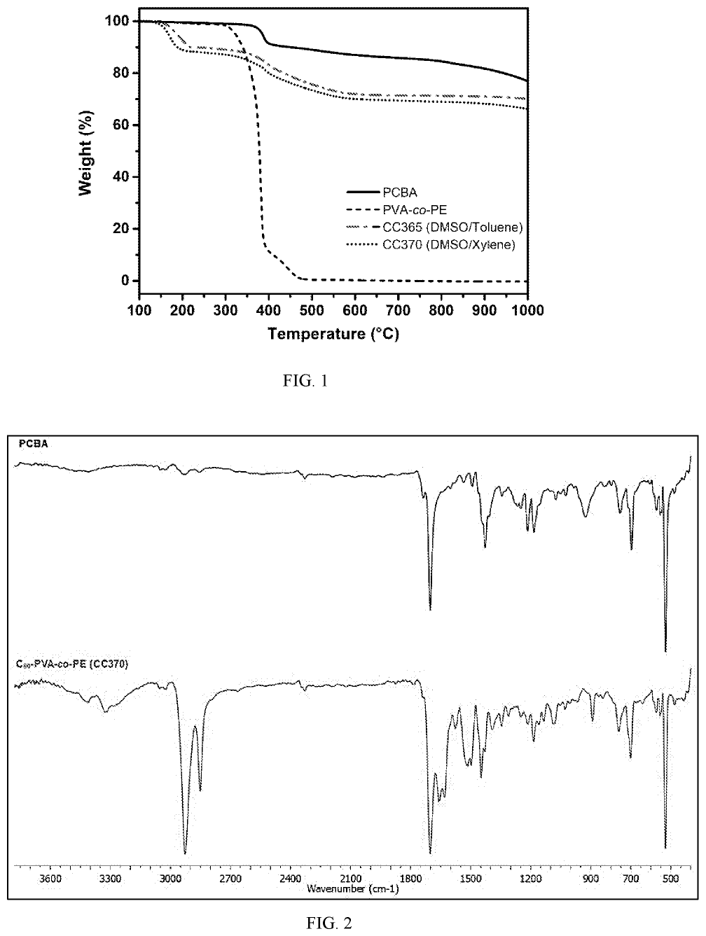

The fullerene derivative PCBA was characterised by thermogravimetric analysis (FIG. 1) and FT-IR spectroscopy (FIG. 2).

### Example 2

Preparation of vinyl polymer functionalized with fullerene C₆₀-PVA-co-PE (CC365)

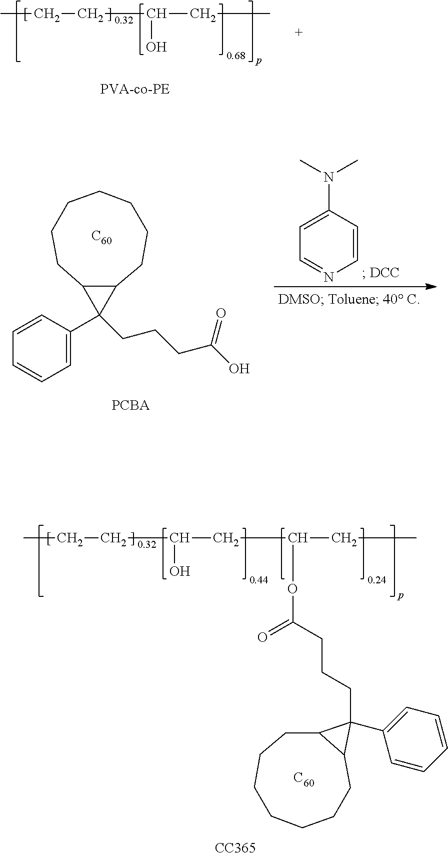

The synthesis of the vinyl polymer functionalized with fullerene C₆₀-PVA-co-PE (CC365) was carried out as follows.

For this purpose, 100 mg of polyvinylalcool-co-ethylene (PVA-co-PE) (Sigma-Aldrich—Lot #MKBV2573—ethylene 32% in moles, Tg=69° C., 1.75 mmoles of —OH groups), were dissolved in 15 ml of a dimethylsulfoxide (DMSO) (Merck—purity >99%)/toluene (VWR—purity >99.5%) mixture (1:1, v/v) in a 100 ml two-neck flask, equipped with a magnetic stirrer, in an inert atmosphere: the reaction mixture was kept, under stirring, at 40° C., for 14 hours. Subsequently, PCBA (547 mg, 0.61 mmol) obtained as described in Example 1, 4-dimethylaminopyridine (DMAP) (Merck—purity >99%) (0.16 mmol) and a solution of N,N′-dicyclohexylcarbodiimide (DCC) (Merck—purity >99%) (1.63 mmol) in 10 ml of a dimethylsulfoxide (DMSO) (Merck—purity >99%)/toluene (VWR—purity >99.5%) mixture (1:1, v/v), were added. The obtained reaction mixture was kept, under stirring, at 40° C., in an inert atmosphere, for 72 hours. Subsequently, the temperature was allowed to drop spontaneously to room temperature (25° C.) and 50 ml of distilled water was added to the reaction mixture, obtaining two phases that were separated using a separating funnel, the aqueous phase was treated with toluene (VWR—purity >99.5%) (3×10 ml) and the organic phases obtained were combined with the former. Subsequently, the toluene was removed by vacuum evaporation at room temperature (25° C.). The solid residue obtained was treated with 25 ml of tetrahydrofuran (THF) [Merck—purity 99.9%—containing 250 ppm butylhydroxytoluene (BHT) previously filtered over neutral alumina in order to remove the BHT present in the commercial product] in order to remove any unreacted PCBA and the suspension obtained was kept, under stirring, at room temperature for 1 hour. Subsequently, the suspension was subjected to centrifugation and traces of insoluble material deposited at the bottom of the vessel were removed by settling and subsequent filtration through a 0.4 mm polytetrafluoroethylene (PTFE) filter. The resulting clear solution was concentrated, under vacuum, at room temperature (25° C.) to a volume of 5 ml and added drop by drop to cold n-hexane (Merck—purity 95%) (100 ml), obtaining the precipitation of a brown solid. This brown solid was recovered by vacuum filtration over a Buchner filter and washed over the filter with cold n-hexane (VWR—purity 95%) (2×10 ml), methanol (Merck) (2×10 ml) and diethyl ether (Merck, >99%) (2×10 ml) and finally dried in an oven at 60° C., overnight, obtaining 384 mg of the fullerene-functionalized vinyl polymer C₆₀-PVA-co-PE (CC365) corresponding to a yield of 61%.

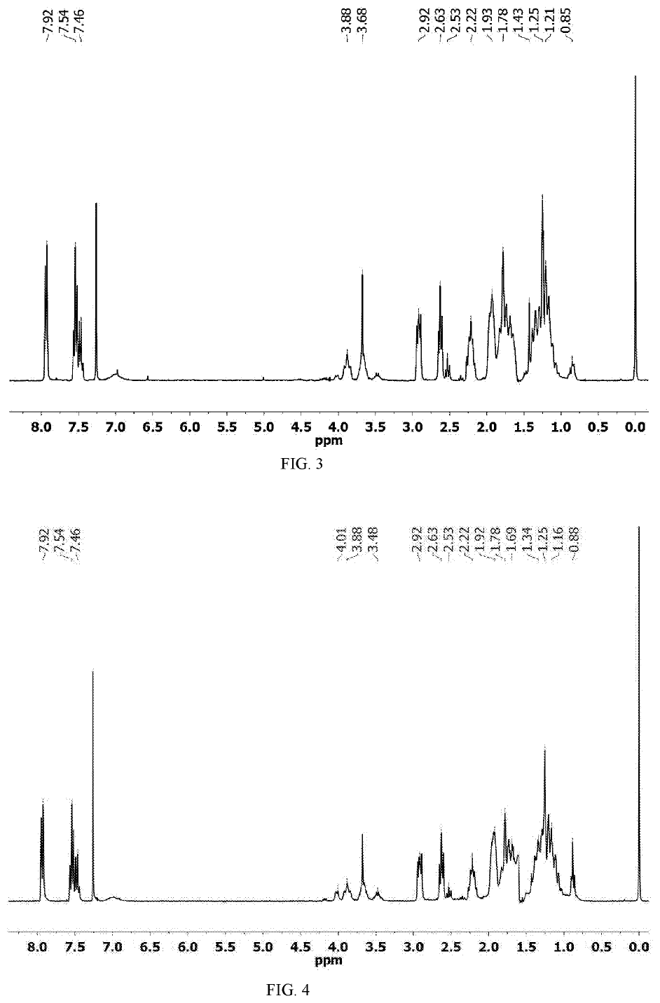

The fullerene-functionalized vinyl polymer C₆₀-PVA-co-PE (CC365) was characterised by ¹H-NMR spectrum [400 MHz, in d′ chloroform (VWR—purity >99.8%),] obtaining the spectrum reported in FIG. 3.

The fullerene-functionalized vinyl polymer C₆₀-PVA-co-PE (CC365) was also characterised by thermogravimetric analysis (FIG. 1), from which it was possible to determine a residual fullerene amount in the polymer equal to 69% by weight: from this data it was inferred that, with reference to the fullerene-functionalized vinyl polymer having general formula (I), x=0.32, y=0.44 and z=0.24 while, from this data the content of —OH groups was calculated which was found to be equal to 3.6% by weight with respect to the total weight of said fullerene-functionalized vinyl polymer C₆₀-PVA-co-PE (CC365).

### Example 3

Preparation of vinyl polymer functionalized with fullerene C₆₀-PVA-co-PE (CC370)

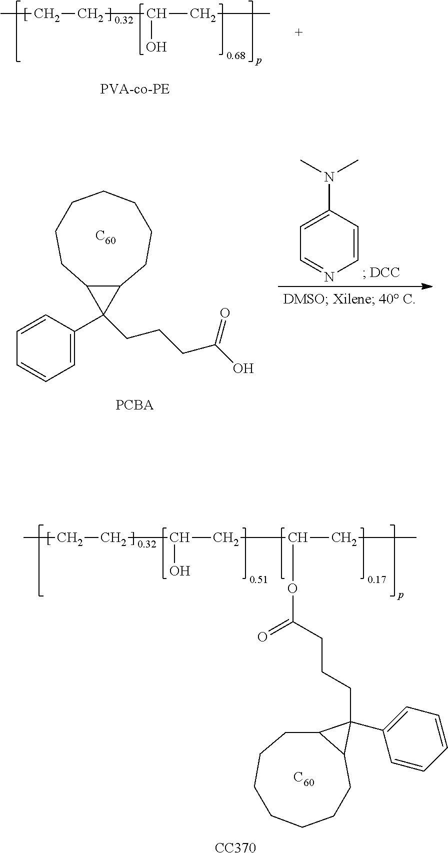

The preparation of the vinyl polymer functionalized with fullerene C₆₀-PVA-co-PE (CC370) was carried out as follows.

For this purpose, 100 mg polyvinylalcool-co-ethylene (PVA-co-PE) (Sigma-Aldrich—Lot #MKBV2573—ethylene 32% in moles, Tg=69° C., 1.75 mmoles of —OH groups), were dissolved in 15 ml of a dimethylsulfoxide (DMSO) (Merck—purity >99%)/xylene (Merck—purity >98%) mixture (1:1, v/v) in a 100 ml two-neck flask, equipped with a magnetic stirrer, in an inert atmosphere: the reaction mixture was kept, under stirring, at 40° C., for 14 hours. Subsequently, PCBA (395 mg, 0.44 mmol) obtained as described in Example 1, 4-dimethylaminopyridine (DMAP) (Merck—purity >99%) (0.16 mmol) and a solution of N,N′-dicyclohexylcarbodiimide (DCC) (Merck—purity 99%) (1.63 mmol) in 10 ml of a mixture of dimethylsulfoxide (DMSO) (Merck—purity >99%)/toluene (VWR—purity >99.5%) (1:1, v/v) were added. The obtained reaction mixture was kept, under stirring, at 40° C., in an inert atmosphere, for 72 hours. Subsequently, operating as described in Example 2, 276 mg of the fullerene-functionalized vinyl polymer C₆₀-PVA(CC370) was obtained, corresponding to a yield of 58%.

The fullerene-functionalized vinyl polymer C₆₀-PVA-co-PE (CC370) was characterised by ¹H-NMR spectrum [400 MHz, in d^{l} chloroform (VWR—purity >99.8%)] obtaining the spectrum reported in FIG. 4.

The fullerene-functionalized vinyl polymer C₆₀-PVA-co-PE (CC370) was also characterized by thermogravimetric analysis (FIG. 1), from which it was possible to determine a residual fullerene amount in the polymer equal to 65% by weight: from this data it was inferred that, with reference to the fullerene-functionalized vinyl polymer having general formula (I), x=0.32, y=0.51 and z =0.17 while, from this data the content of —OH groups was calculated which was found to be equal to 4.6% by weight with respect to the total weight of said fullerene-functionalized vinyl polymer C₆₀-PVA-co-PE (CC370).

The fullerene-functionalized vinyl polymer C₆₀-PVA-co-PE (CC370) was also characterized by IR spectroscopy (FIG. 2), wherein the presence of fullerene units in the polymer can be qualitatively confirmed by the presence of the absorption band at 525 cm⁻¹.

1. A fullerene-functionalized vinyl polymer having general formula (I): 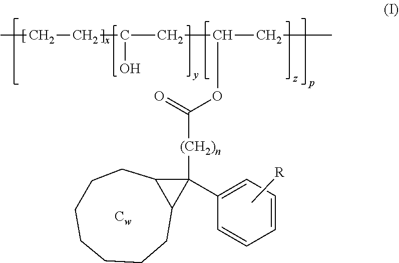
wherein:
x is a fractional number comprised between 0 and 0.89;
y is a fractional number comprised between 0.01 and 0.9;
z is a fractional number comprised between 0.1 and 0.99;
provided that the sum of x+y+z is equal to 1;
p is an integer comprised between 10 and 10000;
w is an integer comprised between 50 and 250;
n is an integer comprised between 1 and 12;
R represents a hydrogen atom; or is selected from C₁-C₂₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups.

2. The fullerene-functionalized vinyl polymer having general formula (I) according to claim 1, wherein said fullerene-functionalized vinyl polymer having general formula (I) has a fullerene content greater than or equal to 35% by weight, with respect to the total weight of said fullerene-functionalized vinyl polymer.

3. The fullerene-functionalized vinyl polymer having general formula (I) according to claim 1, wherein said fullerene-functionalized vinyl polymer having general formula (I) has a content of hydroxyl groups (—OH) greater than or equal to 0.1% by weight, with respect to the total weight of said fullerene-functionalized vinyl polymer having general formula (I).

4. A process for the preparation a fullerene-functionalized vinyl polymer having general formula (I) according to claim 1, comprising reacting at least one vinyl polymer having general formula (II): 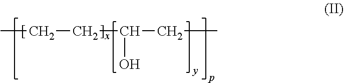
x is a fractional number comprised between 0 and 0.99;
y is an integer or fractional number comprised between 0.01 and 1;
provided that the sum of x+y is equal to 1;
p is an integer comprised between 10 and 10000;
with at least one fullerene derivative having general formula (III): 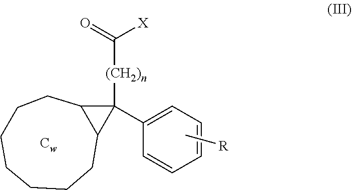
wherein R, n and w have the same meanings reported above and X represents a hydroxide anion, or a halide anion such as chloride, bromide, iodide;
in the presence of:
an organic solvent or a mixture of organic solvents;
at least one substituted pyridine having general formula (IV): 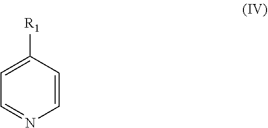
wherein R₁ represents a hydrogen atom; or is selected from C₁-C₂₀, linear or branched, saturated or unsaturated, alkyl groups, optionally containing heteroatoms, optionally substituted aryl groups, optionally substituted heteroaryl groups, optionally substituted cycloalkyl groups, optionally substituted heterocyclic groups; or C₁-C₂₀, linear or branched, saturated or unsaturated, dialkyl-amino groups, C₁-C₂₀, linear or branched, saturated or unsaturated, alkoxy groups, amino group, cyano group, hydroxy group;
at least one substituted carbodiimide having general formula (V): 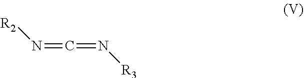
wherein R₂ and R₃, mutually identical or different, are selected from C₁-C₂₀, linear or branched, saturated or unsaturated, alkyl groups, optionally containing heteroatoms, optionally substituted aryl groups, optionally substituted cycloalkyls, optionally substituted heterocyclic groups.

5. The process for the preparation of a fullerene-functionalized vinyl polymer having general formula (I) according to claim 4, wherein said organic solvent is selected from dimethylsulfoxide (DMSO), xylene, toluene, mesitylene, tetrahydrofuran (THF), methyltetrahydrofuran (Me-TIF), dioxane.

6. The process for the preparation of a fullerene-functionalized vinyl polymer having general formula (I) according to claim 4, wherein said mixture of organic solvents is a mixture of organic solvents selected from dimethyl sulfoxide (DMSO), xylene, toluene, mesitylene, in 1/1 v/v ratio.

7. The process for the preparation of a fullerene-functionalized vinyl polymer having general formula (I) according to claim 4, wherein said vinyl polymer having general formula (II) and said fullerene derivative having general formula (III) are used in molar ratio with respect to the quantity in moles of the —OH groups contained in said vinyl polymer having general formula (II), comprised between 10 and 0.1.

8. The process for the preparation of a fullerene-functionalized vinyl polymer having general formula (I) according to claim 4, wherein said substituted pyridine having general formula (IV) is selected from 4-dimethylaminopyridine (DMAP), 4-methylpyridine, 4-tert-butylpyridine, 4-vinylpyridine, 4-methoxypyridine, 4-hydroxypyridine, or mixtures thereof.

9. The process for the preparation of a fullerene-functionalized vinyl polymer having general formula (I) according to claim 4, wherein said carbodiimide having general formula (V) is selected from NN-diethylcarbodiimide, N,N′-di-iso-propylcarbodiimide, N,N-di-3-dimethylaminopropylcarbodiimide, N,N-dicyclohexylcarbodiimide (DCC), or mixtures thereof.

10. The process for the preparation of a fullerene-functionalized vinyl polymer having general formula (I) according to claim 4, wherein said substituted pyridine having general formula (IV) is used in molar ratio, with respect to total moles of the fullerene derivative having general formula (III), comprised between 0.9 and 0.1.

11. The process for the preparation of a fullerene-functionalized vinyl polymer having general formula (I) according to claim 4, wherein said carbodiimide having general formula (V) is used in molar ratio, with respect to total moles of the fullerene derivative having general formula (III), comprised between 9 and 1.

12. The process for the preparation of a fullerene-functionalized vinyl polymer having general formula (I) according to claim 4, wherein said process is carried out:
at a temperature comprised between 15° C. and 150° C.; and/or
for a time comprised between 2 hours and 96 hours.

13. Organic photovoltaic device (or solar device) such as an organic, binary, ternary, quaternary solar cell, having simple or “tandem” architecture, an organic photovoltaic module (or solar module), on a rigid support or on a flexible support, comprising at least one fullerene-functionalized vinyl polymer having general formula (I) according to claim 1.

14. Perovskite-based photovoltaic (or solar cell) wherein the electron transport layer (ETL) comprises at least one fullerene-functionalized vinyl polymer having general formula (I) according to claim 1.

15. Organic thin film transistors (OTFTs), or organic field effect transistors (OFETs) comprising at least one fullerene-functionalized vinyl polymer having general formula (I) according to claim 1.
